(19) United States
(12) Patent Application Publication
(10) Pub. No.: US 2026/0359501 A1
(43) Pub. Date: Nov. 12, 2026

(54) Computer-Implemented Reverse Engineering of Terrazzo Designs

(71) Applicant: Kivanc Bugra Yavuz, Wayne, NJ (US)

(72) Inventor: Kivanc Bugra Yavuz, Wayne, NJ (US)

(21) Appl. No.: 19/204,500

(22) Filed: May 10, 2025

(51) Int. Cl. G06F 30/13; G06T 7/11; G06T 7/194; G06T 7/90

(52) U.S. Cl. CPC G06F 30/13; G06T 7/11; G06T 7/194; G06T 7/90; G06T 2200/24; G06T 2207/10024

(57) ABSTRACT

A computer-implemented system and method for reverse engineering terrazzo surface designs from digital images. The system receives an image of a terrazzo surface, detects a dominant epoxy background color, and identifies aggregate color clusters using clustering algorithms. Detected aggregates are matched with entries in a predefined catalog. A simulated terrazzo layout is generated based on selected aggregate types, sizes, and coverage percentages. A graphical user interface allows users to upload images, modify design parameters, preview terrazzo simulations, and export digital terrazzo patterns with associated metadata.

### FIELD OF THE INVENTION

The present invention relates to the field of terrazzo flooring and surface design. More particularly, the invention relates to computer-implemented systems and methods for analyzing, simulating, reverse engineering, and generating digital terrazzo surface designs, including epoxy color detection, aggregate analysis, and digital sample generation.

### BACKGROUND OF THE INVENTION

Traditional terrazzo design and sample reproduction require significant manual effort and trial-and-error processes, especially when attempting to replicate an existing terrazzo surface. Architects and manufacturers often face difficulty identifying the aggregates, proportions, and epoxy colors used in existing terrazzo installations. This lack of reliable analytical tools makes visual matching inefficient and subjective. A need therefore exists for a system capable of automatically analyzing terrazzo images, identifying their components, and generating accurate digital replicas that can be used for design, simulation, and manufacturing planning.

### SUMMARY OF THE INVENTION

The invention provides a computer-implemented system and method that enables users to analyze terrazzo surfaces and generate simulated terrazzo layouts.

The system is configured to: receive and analyze terrazzo sample images, detect dominant epoxy colors, identify aggregate color clusters, match detected aggregates with entries in a predefined catalog, generate a simulated terrazzo layout, and export digital samples and associated metadata. The invention bridges the gap between physical terrazzo samples and their digital reproduction by enabling automated analysis and simulation.

### BRIEF DESCRIPTION OF THE DRAWINGS

FIG. 1 illustrates a system flow diagram of the terrazzo reverse engineering process.

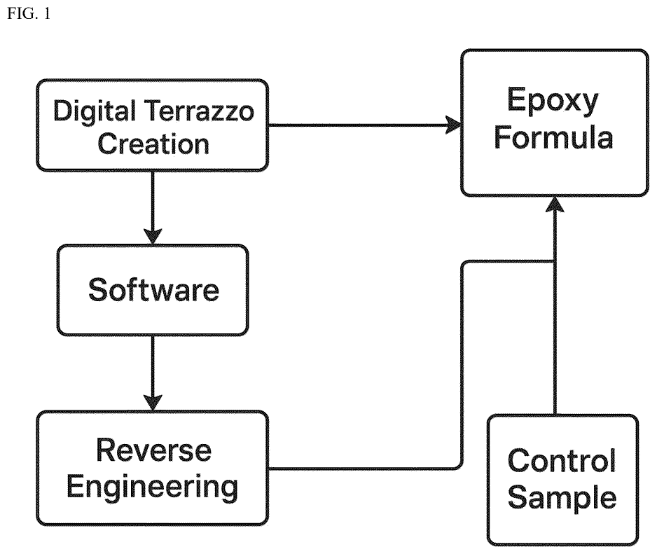

FIG. 2 illustrates a graphical user interface used for terrazzo analysis.

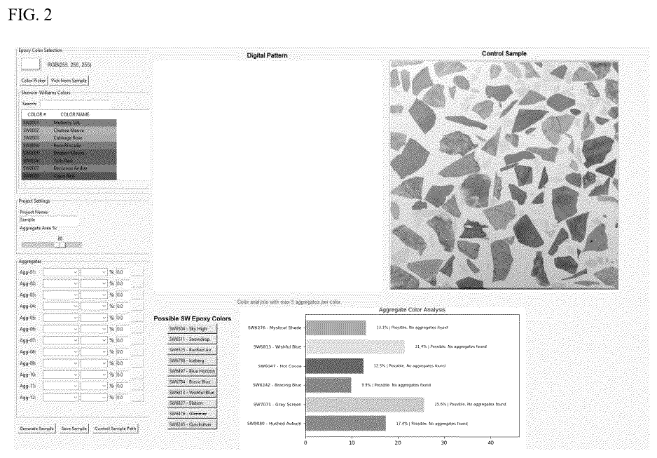

FIG. 3 illustrates the digital terrazzo design interface layout.

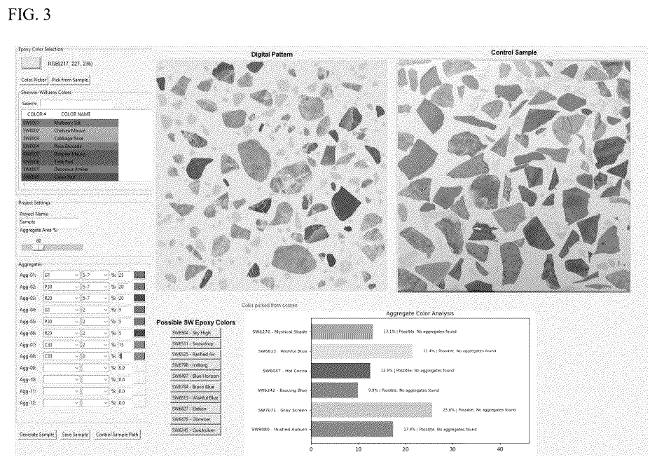

FIG. 4 illustrates a bar chart representing aggregate color clustering analysis.

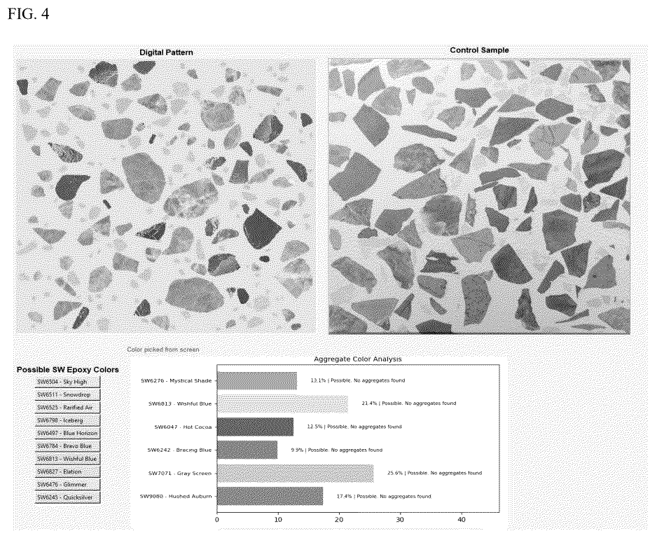

FIG. 5 illustrates an exported terrazzo simulation including metadata and layout information.

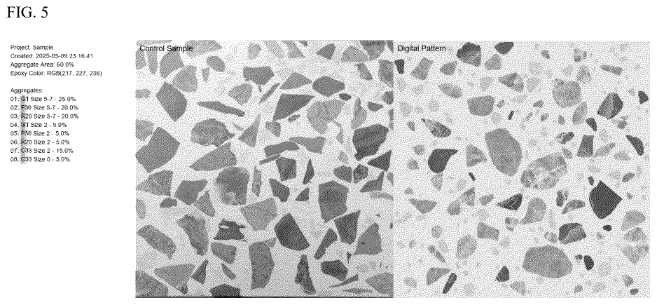

### DETAILED DESCRIPTION OF THE INVENTION

The invention may include a computer-implemented system comprising image processing modules, clustering algorithms, and a graphical user interface.

### Terrazzo Image Analysis

A user uploads an image of a terrazzo sample. The system detects the dominant epoxy background color and segments non-background regions representing aggregate particles. Color clustering algorithms are applied to identify representative aggregate groups.

### Aggregate Placement Engine

Selected aggregates are digitally placed onto a virtual canvas. Aggregate elements may be randomly rotated and positioned using a non-overlapping placement algorithm while maintaining a target aggregate coverage percentage.

### Epoxy Color Selection

Users may select epoxy colors manually or automatically using RGB matching against a predefined color catalog.

### Export Engine

The resulting terrazzo layout may be exported as image files, reports, or metadata files describing aggregate composition and layout parameters.

1-7. (canceled)

8. A computer-implemented method for reverse engineering a terrazzo surface design from an input image, the method comprising:
receiving, by a computing device comprising at least one processor and memory, an image representing a terrazzo surface;
detecting a dominant epoxy background color within the image;
segmenting non-background regions of the image to identify aggregate regions;
performing color clustering on the aggregate regions to determine representative aggregate color groups;
matching the representative aggregate color groups to entries in a predefined material or color catalog;
computationally generating a physically realizable terrazzo layout based on selected aggregate types, aggregate sizes, and aggregate percentage coverage, the generated layout being usable for digital visualization, design simulation, and manufacturing planning;
simulating spatial distribution of aggregates using a non-overlapping placement process configured to approximate a real terrazzo casting layout; and
rendering a simulated terrazzo surface design on a digital canvas.

9. The method of claim 8, wherein computationally generating the physically realizable terrazzo layout further comprises placing aggregate elements onto the digital canvas using a non-overlapping placement algorithm configured to prevent intersection between aggregates while maintaining a predefined aggregate surface coverage percentage.

10. A computer-implemented system for reverse engineering terrazzo surface designs, comprising:
one or more processors;
a memory storing instructions that when executed cause the system to:
receive an image of a terrazzo sample;
detect a dominant epoxy background color;
identify aggregate color clusters;
match detected aggregate colors with entries in a predefined material or color catalog;
generate a digital terrazzo layout; and
display the generated terrazzo layout through a graphical user interface configured to allow a user to upload images, modify design parameters, preview simulated layouts, and export generated terrazzo samples including associated metadata.
